(19) United States
(12) Patent Application Publication
(10) Pub. No.: US 2009/0277670 A1
(43) Pub. Date: Nov. 12, 2009

(54) High Density Printed Circuit Board Interconnect and Method of Assembly

(76) Inventors: Roger A. Booth, JR., Wappingers Falls, NY (US); John R. Dangler, Rochester, MN (US); Matthew S. Doyle, Rochester, MN (US); Jesse M. Hefner, Rochester, MN (US); Thomas W. Liang, Rochester, MN (US); Ankur K. Patel, Rochester, MN (US); Paul W. Rudrud, Rochester, MN (US)

Correspondence Address: CANTOR COLBURN LLP - IBM ROCHESTER DIVISION, 20 Church Street, 22nd Floor, Hartford, CT, 06103, US

(21) Appl. No.: 12/118,696

(22) Filed: May 10, 2008

(51) Int. Cl. H05K 1/02

(52) U.S. Cl. 174/255

(57) ABSTRACT

A printed circuit board assembly having an edge joined first and second sub-circuit board is provided. The first sub-circuit board includes an edge with a stair-step profile interconnection wherein each of the stairs on the profile exposes an area of a signal layer. Each exposed portion of the signal layer has a plurality of signal pads thereon. The second sub-circuit board includes an edge with an inverse stair-step profile interconnection. A pad-on-pad connector is positioned in-between and electrically interconnects the respective signal layers on each sub-circuit board.

### BACKGROUND

This disclosure relates to a printed circuit board having first and second circuit board joined together and in particular to a printed circuit board having pad-to-pad connectors coupling adjoining signal layers between the first and second circuit board.

Printed circuit boards (“PCB”) are generally fabricated from a plurality of laminated layers. Each of the layers typically consist of a core being fabricated from an insulating material, such as FR-4, epoxy glass, polyester or synthetic resin bonded paper for example. Typically, a copper layer is bonded to one or both sides of the core. Circuits or “traces” are formed on the copper by applying a mask and removing unneeded copper. The individual layers are then laminated together to form the PCB.

Due to constraints in the manufacturing processes, the size of the PCB is limited. To accommodate the need for larger PCBs_ and backplanes, various methods of joining multiple PCBs_ have been proposed. One such method is illustrated in FIG. 1. The first PCB 10 is arranged adjacent a second PCB 12. The PCBs 10, 12 are coupled together by one or more plates 14 that include one or more bolted joints 16_. The passing of signals is accomplished using external cards 18. These cards connect to the signal layers of the respective PCB 10, 12 by through vias 20. A connector 22 couples the external cards 18.

The external card approach provides a means for coupling together multiple PCBs, however, there are several drawbacks. The external cards 18 require additional height or add undesired thickness to the PCBs_and therefore can not be used in applications with space constraints. The connections also require through-vias 20 which are expensive to manufacture are parasitic in nature and adversely impact the impedance. Further, the external cards 18 require internal PCB vias within the card 18 which reduces signal quality.

While existing systems for coupling multiple PCBs_ are adequate for their intended purposes, it is desirable to have a PCB assembled from multiple PCBs that requires provides a smaller profile and improves signal quality between the circuit boards.

### SUMMARY

A printed circuit board assembly is provided having a first printed circuit board. The first printed circuit board includes a first signal layer having a first side and a second signal layer. The first and second signal layers are positioned in a laminate arrangement wherein one end of said first layer extends beyond said second layer by a first distance. A second printed circuit board is also provided having a third signal layer. The third signal layer has a second and fourth signal layers that are positioned in a laminate arrangement wherein said third layer extends beyond said second layer by said first distance. A conductor is positioned between and electrically coupling the first signal layer first side and said third signal layer second side.

Another printed circuit board embodiment is also provided having a first printed circuit board. The first printed circuit board includes a first core having a first signal layer and a second signal layer. A first fill layer is arranged in contact with the second signal layer. A second core having a third signal layer and a fourth signal layer is arranged such that said third signal layer is in contact with the fill layer. The second core is positioned with an end offset from an end of said first core by a first distance. A second printed circuit board is also provided having a third core having a fifth signal layer and a sixth signal layer. A second fill layer is in contact with the fifth signal layer. A fourth core having a seventh and eighth signal layer is positioned such that the third signal layer is in contact with the second fill layer. The fourth core is positioned with an end offset from an end of the third core by the first distance. A connector is also provided between the first fill layer and the second fill layer, wherein the connector electrically couples the second signal layer and the seventh signal layer.

Another printed circuit board embodiment is provided with a first circuit board having a plurality of cores. Each of the cores has a first and second signal layer and is further separated by a nonconductive first fill layer. The plurality of cores is positioned such that the first signal layer of each core extends beyond the adjacent first fill layer to define a stair-step profile arrangement. A second circuit board is provided also having a plurality of cores. Each of the second circuit board cores has a third and fourth signal layer. A nonconductive second fill layer also separates each of the second circuit board cores. The plurality of second circuit board cores are positioned such that the fourth signal layer of each core extends beyond the adjacent second fill layer to define an inverted stair step profile arrangement. The second circuit board is positioned in series with the first circuit board wherein each of the first signal layers is electrically coupled to one of the fourth signal layers.

### BRIEF DESCRIPTION OF FIGURES

FIG. 1 is a perspective view illustration of a prior art edge joining arrangement for printed circuit boards using an external card;

FIG. 2 is an exploded perspective view illustration of an exemplary embodiment printed circuit board interconnect;

FIG. 3 is an exploded side plan view illustration of circuit board interconnect of FIG. 2;

FIG. 4 is a side plan view illustration of the printed circuit board interconnect of FIG. 2;

FIG. 5 is a top plan view illustration of an alternate embodiment circuit board have interconnections on opposing sides; and,

FIG. 6 is a top plan view illustration of another alternate embodiment circuit board having interconnections on two sides.

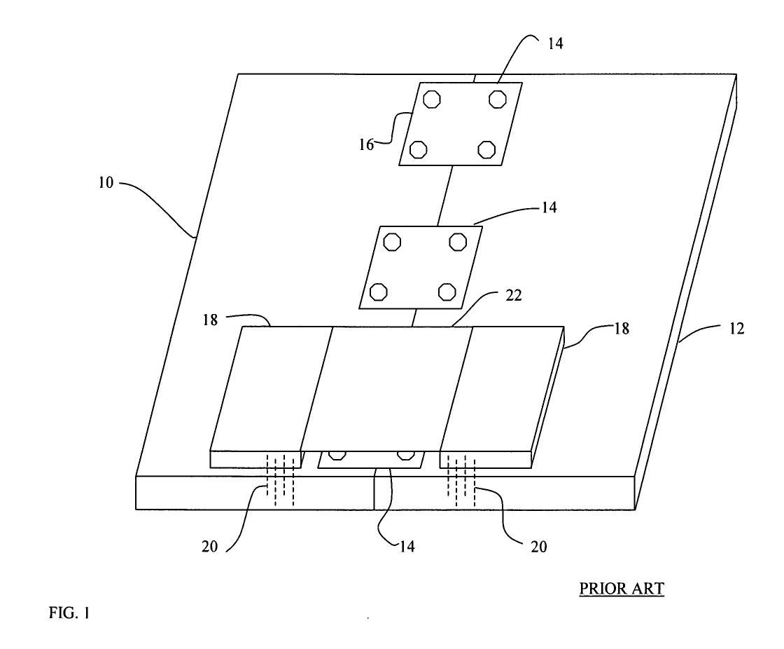

### DETAILED DESCRIPTION

The use of the terms “a” and “an” and “the” and similar references in the context of describing the invention (especially in the context of the following claims) are to be construed to cover both the singular and the plural, unless otherwise indicated herein or clearly contradicted by context. The modifier “about” used in connection with a quantity is inclusive of the stated value and has the meaning dictated by the context (e.g., it includes the degree of error associated with measurement of the particular quantity). All ranges disclosed herein are inclusive of the endpoints, and the endpoints are independently combinable with each other.

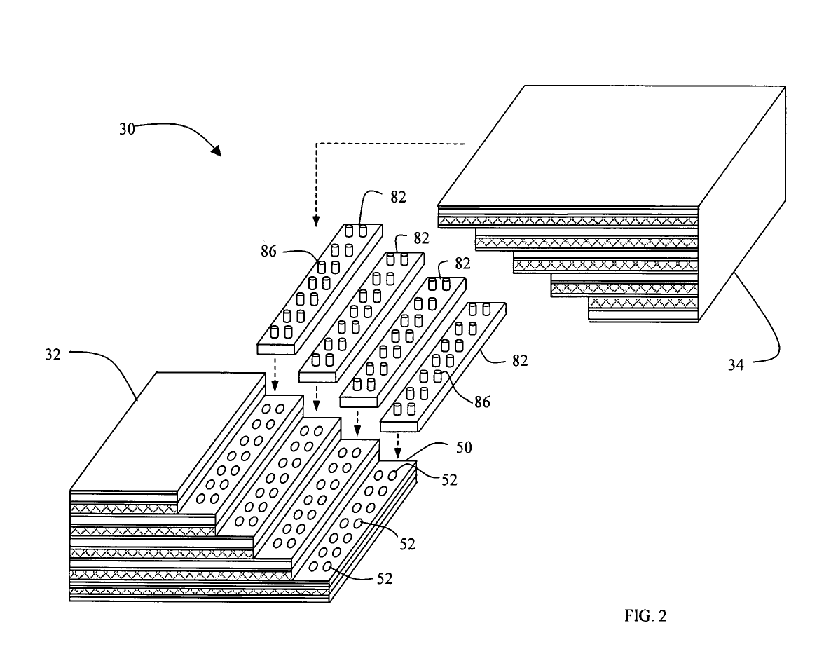

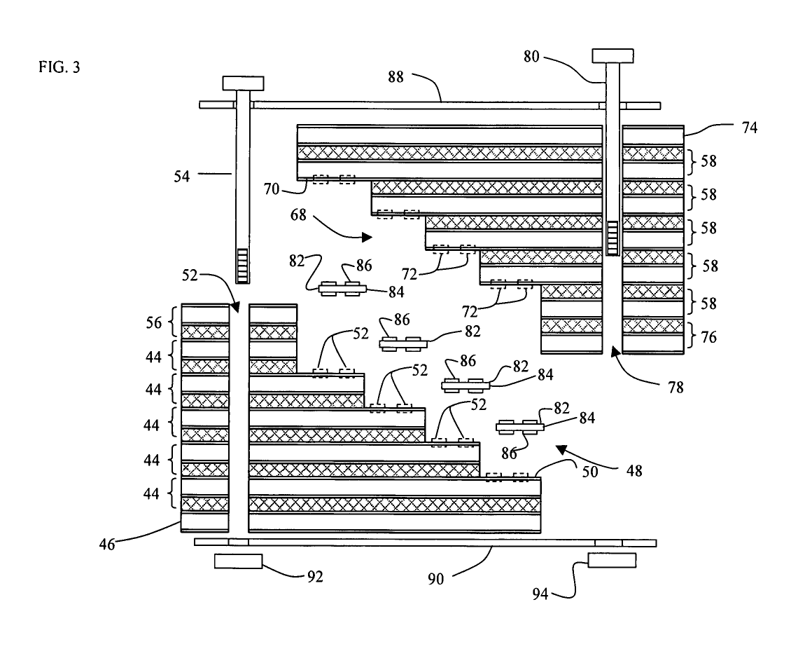

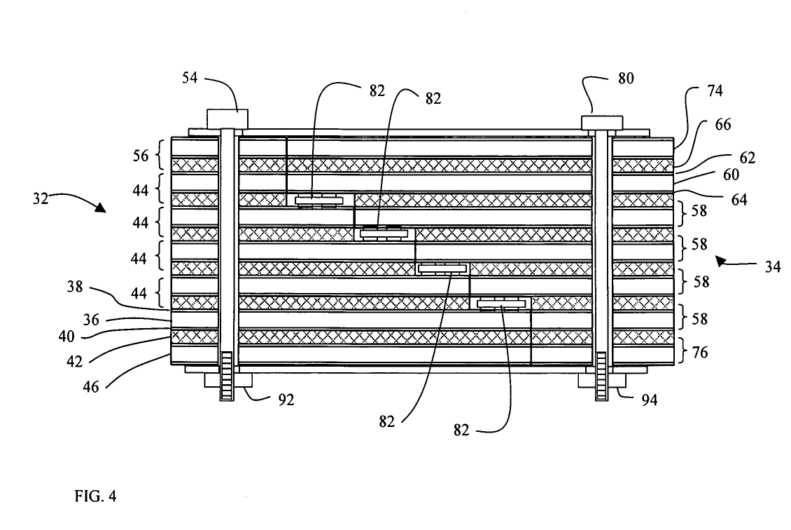

With reference now to FIGS. 2-4 an exemplary depiction of an interlocked printed circuit board (PCB) is illustrated. Due to increased performance requirements, larger PCBs_ are required to provide the needed performance. However, existing manufacturing processes are constrained in terms of the physical size board that may be fabricated. A typical PCB used in the computer electronics field may be approximately 10 cm wide and 31 cm long. However, some PCBs can be more than twice those dimensions. While changes to the current processes may allow the fabrication of larger board, these changes are cost prohibitive. To accommodate this, the PCB 30 includes a first sub-circuit board 32 and a second sub-circuit board 34 which interconnect to create a larger circuit board. In one embodiment, the interconnections may be made on multiple sides of the sub-circuit boards to create a PCB 30 of virtually any desired size or shape.

In the exemplary embodiments, the sub-circuit boards 32, 34 are multi-layer printed circuit boards. The PCBs are made by bonding a layer of copper over a substrate, referred to as a core, to form a blank board. The core may be manufactured from any suitable nonconductive material such as fiberglass, polyimide, FR-4, FR-2, BT-Epoxy, cyanate ester, pyrlux, or polytetraflouroethylene for example. In the exemplary embodiment, the sub-circuit boards 32, 34 include a copper layer on both sides of the core.

Once the copper layers are bonded, the layers are then subsequently processed to remove un-needed copper and create the desired “traces” or signal paths on each side of the core. The traces may be formed to using a mask that protects the traces during subsequent etching processes. Several different processes may be used to remove the copper, such as but not limited to silkscreen printing and etching, photoengraving, and milling. Alternative processes for forming the board layer also include processes that add the copper traces to the board rather than removing the copper layer.

The sub-circuit board 32, includes a number of individual layers. A layer 44 consists of a core 36 with a first signal layer 38 and a second signal layer 40. A fill layer 42 separates the core 36 and signal layers 38, 40 from the adjacent cores/signal-layers within the sub-circuit board 32. The sub-circuit board 32 may also include optional outer layers 46 to provide a layer for mounting surface mount components for example. In the exemplary embodiment, the sub-circuit board 32 includes six layers with an additional outer layer 46 on one side.

The individual layers 44 are arranged as a laminate to form the sub-circuit board 32. The layers 44 are further arranged with different lengths and the end portions are staggered to form a stair-step profile 48. This arrangement results in a portion 50 of the first signal layer 38 for each layer 44 being exposed when sub-circuit board 32 is in the unassembled state. The sub-circuit board 32 may further include one or more layers 56 that are the same length as the adjacent layer 44. As will be discussed in more detail below, these layers 56 do not interconnect with sub-circuit board 34. Further, it should be appreciated that while the layers 44 are described herein as having a different length, the layers 44 may alternatively be the same length. In this embodiment, two stair-step profiles may be arranged on each end of the sub-circuit board 32. Further, it should be appreciated that while the non-interconnecting layer 56 is illustrated on the side of the sub-circuit board 32, this type of layer 56 may be positioned within the interior of the laminate arrangement as well.

Each exposed portion 50 includes one or more signal pads 52. The signal pads 52 electrically communicate with the traces on the individual layers 44. In the exemplary embodiment, there is a plurality of signal pads extending across the length of the exposed portion 50. The sub-circuit board 32 further includes one or more fastener holes 52 that are sized to receive a fastener, such as bolt 54 for example.

Similar to sub-circuit board 32, sub-circuit board 34 includes a plurality of layers 58. Each layer 58 includes a fill layer 66 adjacent to a core 60. A third signal layer 62 and a fourth signal layer 64 are bonded to the core 60 and have the desired traced formed thereon. The layers 58 are arranged in a laminate manner as described above. The layers are further arranged in an inverse stair-step profile 68. The stair-step profile 68 creates a second exposed portion 70 on each of the fourth signal layers of each layer 58.

In addition to the layers 58, sub-circuit board 34 may further include an optional outer layer 74. Non-interconnected layers 76 may also be included in sub-circuit board 34 as well. Similar to sub-circuit board 32, a fastener hole 78 sized to receive a fastener, such as bolt 80 for example, extends through the laminate. It should be appreciated that sub-circuit board 32 and sub-circuit board 34 are identical-mirror images of each other, at least in the stair-step portions 48, 68.

PCB 30 further includes one or more pad-on-pad connectors 82. The connectors 82 includes a carrier or “interposer body” 84 that provides support for one or more conductive columns 86. The interposer body 84 is made from a nonconductive thermoplastic or elastomer material and is sized to fit within the exposed portions 50, 70. The conductive columns 86 are arranged to align and electrically connect the signal pads 52, 72 when the PCB 30 is assembled. In the exemplary embodiment, the connectors 82 further have some elasticity and are compressible when the PCB is assembled. This elasticity provides a normal force on the respective layers 44, 58 in which the connector 82 is coupled and also reduces the inductance of the conductive column 86. The connector 82 may also be a Land Grid Array (LGA) compression connectors such as the type developed by Tyco® (Tyco electronics is a division of Tyco International Ltd) for example. However, it should be appreciated that other types of conductors, capable of connecting electrical components may also be used.

A pair of plates 88, 90 are arranged on opposite sides of the sub-circuit boards 32, 34 and span across the interconnection of the sub-circuit boards 32, 34. The plates 88, 90 are captured on the PCB 30 by the fasteners 54, 80. A second retaining fastener, such as retaining nuts 92, 94, capture the fasteners 54, 80 and maintain the interconnection between sub-circuit board 32 and sub-circuit board 34.

During the assembly of PCB 30, a connector 82 is positioned on each exposed portion 50 of sub-circuit board 32. The connectors 82 include a conductive column 86 for each signal pad 52. When assembled, the conductive columns 86 are in electrical contact with the signal pads 52 to transfer signals from the first signal layer 38. It should be appreciated that while the connectors 82 are referred to collectively, each connector 82 may have a different configuration to match that of the corresponding signal pads 52 for the layer 44 on which it is assembled.

After placing the connectors 82 on the exposed portions 50, the second sub-circuit board 34 is placed into an interconnected arrangement with sub-circuit board 32. The exposed portions 70 are arranged in contact with the connectors 82 such that the conductive columns 86 are in electrical contact with the signal pads 72. The plates 88, 90 are positioned over the interconnection point and the retaining fasteners 92, 94, capture the fasteners 54, 80. The tightening of the fasteners 54, 80, 92, 94 causes the connectors 82 to compress slightly as discussed above. This compression provides a normal force on the signal layers, such as first signal layer 38 and fourth signal layer 64 for example, to ensure a positive electrical connection and lower impedance. When assembled and the retaining fasteners 54,80, 92, 94 tightened, the adjoining layers 44, 58 are positioned in the same plane.

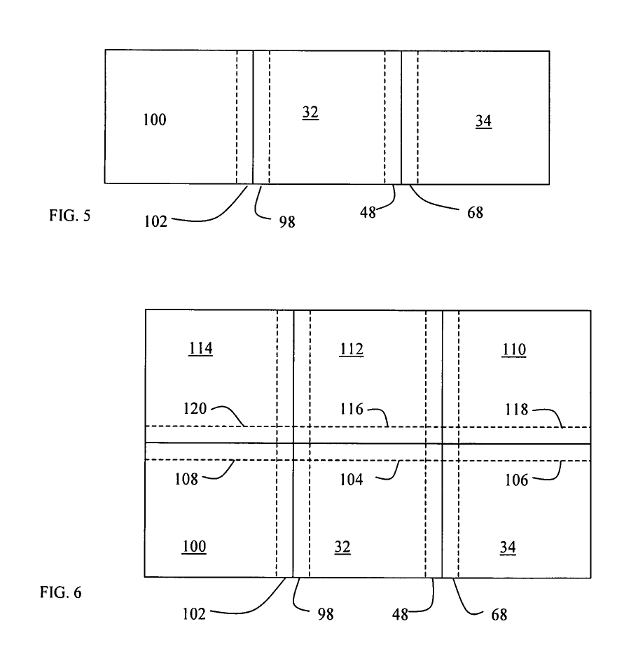

An alternate embodiment PCB 30 is illustrated in FIG. 5. In this embodiment, the sub-circuit board 32 includes a first stair-step portion 48 that interconnects with stair-step portion 68 of sub-circuit board 34. Stair-step portion 48 and stair-step portion 68 provide an interconnection arrangement as described above. Sub-circuit 32 further includes a second stair-step interconnect portion 98 along the edge opposite first stair-step portion 48. Stair-step portion 98 interconnects the sub-circuit board 32 with a third sub-circuit board 100. Similar to sub-circuit boards 32, 34, sub-circuit board 100 includes a stair-step interconnection portion 102 that couples to sub-circuit board 32 using connectors 82 and fasteners as discussed above. This embodiment provides advantages in expanding the PCB 30 to larger sizes. It should be appreciated that sub-circuit board 34 or sub-circuit board 100 may be arranged to include opposing stair-step portions similar to sub-circuit board 32 which would allow the PCB 30 to be extended to any length desired.

Another alternate embodiment of PCB 30 is illustrated in FIG. 6. In this embodiment, the sub-circuit boards each include two stair-step portions along adjoining edges. The sub-circuit board 32 includes stair-step portions 48, 98 that interconnect sub-circuit board 32 with sub-circuit board 34 and sub-circuit board 100 as discussed above. An additional stair-step portion 104 is arranged along the edge of sub-circuit board 32 adjacent or perpendicular to portions 48, 98. Similarly, sub-circuit boards 34, 100 each include stair-step portions 106, 108 respectively. These additional interconnection portions allow the interconnection of a second set of sub-circuit boards 110, 112, 114. These additional sub-circuit boards 110, 112, 114 each include a similar stair-step interconnection portion 118, 116, 120 respectively. It should be appreciated that this arrangement allows the expansion of PCB 30 in two directions allowing the PCB 30 to be made in any desired size.

The printed circuit board stair-step interconnection disclosed herein provides advantages in reliably increasing the size of the printed circuit board. This interconnection arrangement provides further advantages in that it allows multiple printed circuit boards to be edge joined with minimal increases in the thickness of the printed circuit board. The interconnection arrangement provides further advantages in that no through vias are required to make the interconnection which reduces the reduces parasitic impact to signal quality, inductance of the interface, and lowers costs.

The diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention.

What is claimed is:

1. A printed circuit board assembly comprising:
a first printed circuit board having a first signal layer having a first side and a second signal layer, said first and second signal layer being positioned in a laminate arrangement wherein one end of said first signal_layer extends beyond said second signal layer by a first distance;
a second printed circuit board having a third signal layer having a second side and a fourth signal layer, said third and fourth signal layer being positioned in a laminate arrangement wherein said third signal layer extends beyond said fourth signal layer by said first distance; and, a conductor positioned between and electrically coupling said first signal layer first side and said third signal layer second side.

2. The printed circuit board of claim 1 further comprising:
a first signal pad on said first signal layer first side;
a second signal pad on said third signal layer second side; and,
wherein said conductor is a pad on pad conductor having a conductive column in electrically coupling said first signal pad and said second signal pad.

3. The printed circuit board of claim 2 wherein said second signal layer and said third signal layer are arranged in the same plane

4. The printed circuit board of claim 3 wherein said first circuit board further includes a first and second outer layer, and said second printed circuit board includes a third and fourth outer layer, wherein said first outer layer is adjacent said third outer layer and said second outer layer is adjacent said fourth outer layer.

5. The printed circuit board of claim 4 further comprising:
a first plate in contact with said first outer layer and said third outer layer; and
a second plate in contact with said second outer layer and said fourth outer layer, wherein said first and second plate are coupled together.

6. A printed circuit board comprising:
a first printed circuit board including:
a first core having a first signal layer and a second signal layer;
a first fill layer in contact with said second signal layer;
a second core having a third signal layer and a fourth signal layer, said second core arranged such that said third signal layer is in contact with said fill layer, said second core being positioned with an end offset from an end of said first core by a first distance;
a second printed circuit board including:
a third core having a fifth signal layer and a sixth signal layer;
a second fill layer in contact with said fifth signal layer;
a fourth core having a seventh and eighth signal layer, said fourth core being positioned such that said third signal layer is in contact with said second fill layer and said fourth core being positions with an end offset from an end of said third core by said first distance; and,
a connector positioned between said first fill layer and said second fill layer, wherein said connector electrically couples said second signal layer and said seventh signal layer.

7. The printed circuit board of claim 6 wherein said second core is positioned adjacent said fourth core.

8. The printed circuit board of claim 7 wherein said first core is positioned adjacent said third core.

9. The printed circuit board of claim 8 further comprising:
a first plate adjacent said first signal layer and said fifth signal layer; and,
a second plate adjacent said fourth signal layer and said eighth signal layer, wherein said first plate and said second plate are coupled.

10. The printed circuit board of claim 6 wherein:
said second signal layer includes a first plurality of signal pads;
said seventh signal layer includes a second plurality of signal pad; and,
said connector having a plurality of conductive columns, each of said conductive columns electrically coupling one of said first plurality of signal pads with one of said second plurality of signal pads.

11. The printed circuit board of claim 10 wherein said connector has a first thickness prior to being assembled in said printed circuit board and a second thickness after being assembled in said printed circuit board, wherein said second thickness is smaller than said first thickness.

12. The printed circuit board of claim 11 wherein said connector includes an interposer pad coupled to and separating said conductive columns, said interposer pad electrically isolating said second signal layer from said seventh signal layer.

13. A printed circuit board comprising:
a first circuit board having a plurality of cores, each of said cores having a first and second signal layer, each of said cores further being separated by a nonconductive first fill layer, said plurality of cores being positioned such that said first signal layer of each core extends beyond said adjacent first fill layer to define a stair-step profile arrangement;
a second circuit board having a plurality of cores, each of said cores having a third and fourth signal layer, each of said cores being separated by a nonconductive second fill layer, said plurality of cores being positioned such that said fourth signal layer of each core extends beyond said adjacent second fill layer to define an inverted stair step profile arrangement, said second circuit board being positioned in series with said first circuit board wherein each of said first signal layer is electrically coupled to one of said fourth signal layers.

14. The printed circuit board of claim 13 further comprising a plurality of connectors, each of said connectors positioned between one of said first fill layers and an adjacent second filler layer.

15. The printed circuit board of claim 14 wherein each of said plurality of connectors includes a nonconductive interposer body and a plurality of conductive columns extending through said interposer body, said plurality of conductive columns electrically coupling said first signal layer with and adjacent fourth signal layer.

16. The printed circuit board of claim 15 wherein each of said plurality of connectors is compressible, and each of said connectors imparts a normal force on and adjacent first signal layer and fourth signal layer.

17. The printed circuit board of claim 16 further comprising:
a first plate in contact with a first side of said first circuit board and a first side of said second circuit board; and
a second plate in contact with a second side of said first circuit board and a second side of said second circuit board.

18. The printed circuit board of claim 17 further comprising:
a first fastener extending through said first plate, said first circuit board and said second plate; and
a second fastener extending through said first plate, said second circuit board and said second plate.

19. The printed circuit board of claim 18 wherein:
said first circuit board further includes a first outer layer positioned between said plurality of cores and said first plate, said first outer layer having a filler layer and a core layer; and
said second circuit board further includes a second outer layer positioned between said plurality of cores and said first plate, said second outer layer having a filler layer and a core layer.

20. The printed circuit board of claim 19 wherein said first circuit board further includes a third outer layer positioned between said plurality of cores and said second plate, said third outer layer having a filler layer and a core layer; and
said second circuit board further includes a fourth outer layer positioned between said plurality of cores and said second plate, said fourth outer layer having a filler layer and a core layer.
